(19) United States
(12) Patent Application Publication
(10) Pub. No.: US 2013/0328010 A1
(43) Pub. Date: Dec. 12, 2013

(54) LIGHT-EMITTING DIODE AND METHOD FOR MANUFACTURING THE SAME

(71) Applicant: LEXTAR ELECTRONICS CORPORATION, Hsinchu (TW)

(72) Inventors: Chang-Chin Yu, Zhubei City (TW); Hsiu-Mu Tang, Hsinchu City (TW); Mong-Ea Lin, Taipei City (TW)

(73) Assignee: LEXTAR ELECTRONICS CORPORATION, Hsinchu (TW)

(21) Appl. No.: 13/793,850

(22) Filed: Mar. 11, 2013

(30) Foreign Application Priority Data
Jun. 7, 2012 (TW) 101120486

(51) Int. Cl. H01L 33/04; H01L 33/32

(52) U.S. Cl. CPC H01L 33/04; H01L 33/32
USPC 257/13; 438/47

(57) ABSTRACT

A high brightness light-emitting diode free of p-type gallium nitride (GaN) layer is provided, which includes an n-type semiconductor layer, a multi-quantum well (MQW) layer, a p-type indium gallium nitride (InGaN) layer and an indium tin oxide (ITO) layer. The grain size of the ITO layer is ranging from 5 to 1000 angstroms. A method for manufacturing the high brightness light-emitting diode is also provided.

### RELATED APPLICATIONS

This application claims priority to Taiwan Application Serial Number 101120486, filed Jun. 7, 2012, which is herein incorporated by reference.

### BACKGROUND

1. Technical Field

The present disclosure relates to a light-emitting diode (LED) and a method for manufacturing the same, and more particularly, to a high brightness LED and a method for manufacturing the same.

2. Description of Related Art

Å light-emitting diode (LED) is a photoelectric conversion device, with an n-type semiconductor connected to a p-type semiconductor, which emits light by recombination of electrons and holes. Recently, the LED has been widely applied in backlight modules and the field of lighting due to having long life and a small size.

The gallium nitride (GaN) based LED is the most representative LED. The GaN-based LED includes a light-emitting cell composed of an n-type GaN layer, a multi-quantum well (MQW) layer (i.e., an active layer) and a p-type GaN layer. However, each of the aforementioned layers would absorb light emitted from the active layer, resulting in the reduction of light extraction.

Therefore, there is still a need for an improved LED and a method for manufacturing the same to increase the light extraction.

### SUMMARY

One aspect of the present disclosure provides a high brightness LED free of p-type gallium nitride (GaN) layer, which includes an n-type semiconductor layer, a multi-quantum well (MQW) layer, a p-type indium gallium nitride (InGaN) layer and an indium tin oxide (ITO) layer. The grain size of the ITO layer is ranging from 5 to 1,000 angstroms (Å). The n-type semiconductor layer is disposed on a substrate. The MQW layer is disposed on the n-type semiconductor layer. The p-type InGaN layer is disposed on the MQW layer. The ITO layer is disposed on the p-type InGaN layer.

Another aspect of the present disclosure provides a method for manufacturing the high brightness LED, which includes the steps below. A substrate is provided. An n-type semiconductor layer is formed on the substrate. The MQW layer is formed on the n-type semiconductor layer. The p-type InGaN layer is formed on the MQW layer. The ITO layer is formed on the p-type InGaN layer. The grain size of the ITO layer is ranging from 5 to 1,000 Å.

### BRIEF DESCRIPTION OF THE DRAWINGS

The disclosure may be more fully understood by reading the following detailed description of the embodiment, with reference made to the accompanying drawings as follows:

FIG. 1 is a schematic diagram of an LED according to one embodiment of the present disclosure;

FIG. 2 is a schematic diagram of an LED according to another embodiment of the present disclosure;

FIG. 3 is a flow chart of a method for manufacturing an LED according to one embodiment of the present disclosure;

FIG. 4 is a cross-sectional view schematically illustrating a process step for manufacturing an LED according to one embodiment of the present disclosure;

FIG. 5 is a cross-sectional view schematically illustrating a process step for manufacturing an LED according to another embodiment of the present disclosure; and

FIG. 6 is a cross-sectional view schematically illustrating a process step for manufacturing an LED according to further embodiment of the present disclosure.

### DETAILED DESCRIPTION

The present disclosure is described by the following specific embodiments. Those with ordinary skill in the arts can readily understand the other advantages and functions of the present invention after reading the disclosure of this specification. The present disclosure can also be implemented with different embodiments. Various details described in this specification can be modified based on different viewpoints and applications without departing from the scope of the present disclosure.

As used herein, the singular forms “a,” “an” and “the” include plural referents unless the context clearly dictates otherwise. Therefore, reference to, for example, a data sequence includes aspects having two or more such sequences, unless the context clearly indicates otherwise.

Reference will now be made in detail to the embodiments of the present disclosure, examples of which are illustrated in the accompanying drawings. Wherever possible, the same reference numbers are used in the drawings and the description to refer to the same or like parts.

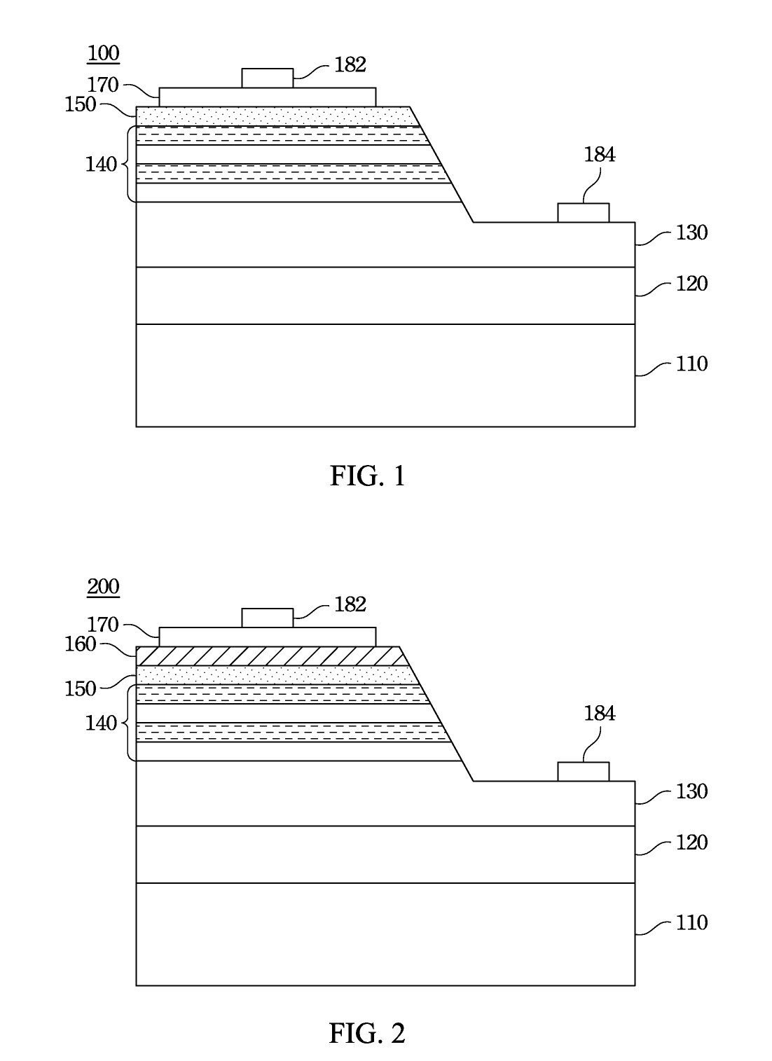

FIG. 1 is a schematic diagram of an LED according to one embodiment of the present disclosure. One aspect of the present disclosure provides a high brightness LED 100 free of p-type gallium nitride (GaN) layer, which includes an n-type semiconductor layer 130, a multi-quantum well (MQW) layer 140, a p-type indium gallium nitride (InGaN) layer 150 and an indium tin oxide (ITO) layer 170.

The n-type semiconductor layer 130 is disposed on a substrate 110. In one embodiment, the n-type semiconductor layer includes n-type gallium nitride (n-type GaN). The substrate 110 is made of glass, quartz, sapphire, silicon carbide, gallium nitride, aluminum nitride or other suitable materials. The n-type semiconductor layer 130 can be formed by performing a chemical vapor deposition (CVD) process and a doped process in sequence. The n-type semiconductor layer 130 may be III-V group semiconductor compounds, such as silicon-doped GaN compounds, but not limited thereto.

In one embodiment, the LED 100 further includes an undoped GaN (U-GaN) layer 120 interposed between the n-type semiconductor layer 130 and the substrate 110. The U-GaN layer 120 is acted as a buffer layer, and it can be formed by a CVD process.

The MQW layer 140 is disposed on the n-type semiconductor layer 130. In one embodiment, the MQW layer 140 is a structure composed of InₓGa₁₋ₓN (0<x<1) layers and GaN layers interstacked with each other, and those layers can be formed by CVD processes. The MQW layer 140 is used to confine carriers in the quantum wells to enhance luminous intensity.

The p-type InGaN layer 150 is disposed on the MQW layer 140. The p-type InGaN layer 150 has a p-type dopant which is a material selected from the group consisting of beryllium (Be), magnesium (Mg) and a combination thereof. The p-type InGaN layer 150 includes a material having a general formula of p-InₓGa₁₋ₓN, in which 0<x<1.In one embodiment, the p-type InGaN layer 150 has a thickness ranging from 5 to 1,000 Å, preferably ranging from 5 to 20 Å, to reduce light absorption thereof. That is, the thin p-type InGaN layer 150 helps to significantly decrease light absorption and thus increase light extraction of the LED 100.

The ITO layer 170 is disposed on the p-type InGaN layer 150, which is used to uniformly spread a current. In order to decrease light absorption of the p-type InGaN layer 150, the thickness thereof is reduced. However, the reduction of the thickness of the p-type InGaN layer 150 deteriorates its ability of uniformly spreading a current. As such, in one embodiment, the ITO layer 170 is formed by a sputtering process. The sputtering process can be carried out to form a denser ITO layer 170 having higher quality to greatly enhance the ability of uniformly spreading a current compared to an e-gun evaporation process. In one embodiment, the grain size of the ITO layer 170 is in a range of 5 to 1,000 Å. Also, in the condition of forming the ITO layer at the same thickness, the ITO layer 170 formed by the sputtering process has lower surface resistance than that formed by the e-gun process. Therefore, in one embodiment, the ITO layer 170 has a surface resistance ranging from 5 to 100 ohms/sq. In one embodiment, the ITO layer 170 has a thickness ranging from 5 to 1,000 angstroms. In other words, the thin ITO layer can reduce light absorption and exhibit enough low surface resistance and good current spreading effect. Further, a good ohmic contact between the ITO layer 170 and the p-type InGaN layer 150 is formed.

In one embodiment, the LED 100 further includes an alkaline earth metal alloy layer 160 interposed between the p-type InGaN layer 150 and the ITO layer 170, as shown in FIG. 2. The alkaline earth metal alloy layer 160 is a material selected from the group consisting of gold-beryllium (AuBe) alloy, gold-magnesium (AuMg) alloy and a combination thereof. The p-type InGaN layer 150 can be formed by annealing the alkaline earth metal alloy layer 160 to diffuse alkaline earth metal ions into the undoped InGaN (U-InGaN) layer. The annealing process would be described in detail below.

Å p-type contacting pad 182 and an n-type contacting pad 184 are respectively disposed on the ITO layer 170 and the exposed portion of the n-type semiconductor layer 130, as shown in FIG. 1 and FIG. 2.

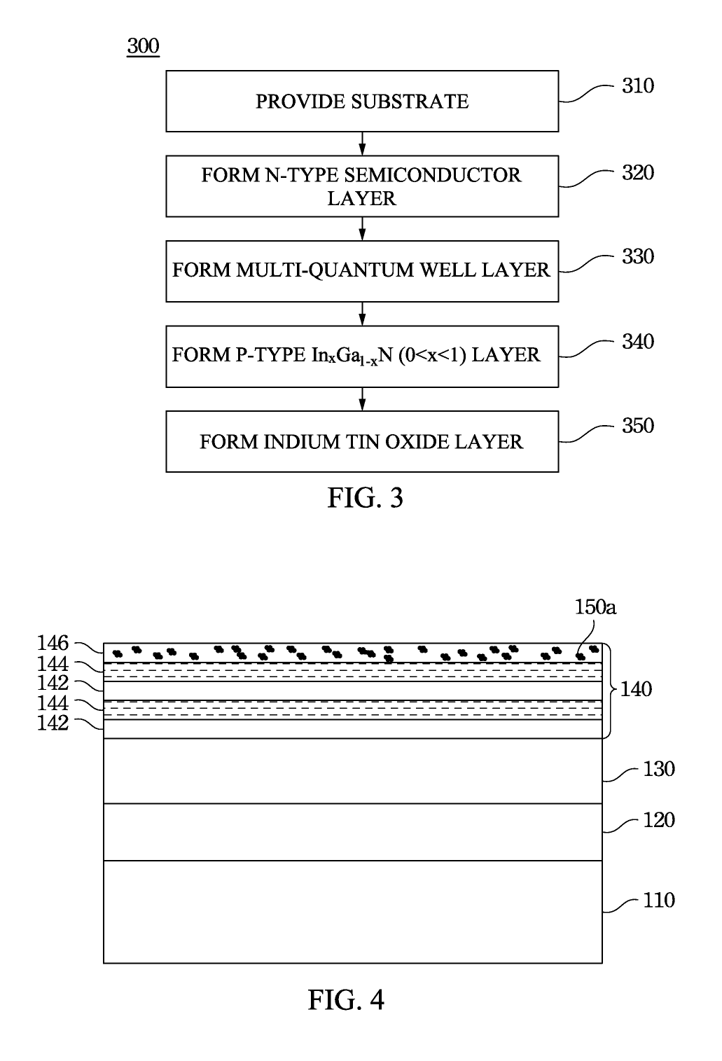

FIG. 3 is a flow chart of a method for manufacturing an LED according to one embodiment of the present disclosure. Another aspect of the present disclosure provides a method for manufacturing the high brightness LED, which includes the steps below.

In step 310, a substrate 110 is provided. In one embodiment, the method 300 further includes a step of forming a U-InGaN layer 120 on the substrate 110. The embodiments of the substrate 110 and the U-InGaN layer 120 may be the same as the embodiments of the substrate 110 and the U-InGaN layer 120 described above in connection with FIG. 1.

In step 320, an n-type semiconductor layer 130 is formed on the substrate 110. The embodiments of the n-type semiconductor layer 130 may be the same as the embodiments of the n-type semiconductor layer 130 described above in connection with FIG. 1.

In step 330, an MQW layer 140 is formed on the n-type semiconductor layer 130. The embodiments of the MQW layer 140 may be the same as the embodiments of the MQW layer 140 described above in connection with FIG. 1.

In step 340, a p-type InGaN layer 150 is formed on the MQW layer 140. The p-type InGaN layer 150 may be formed by an organometallic chemical vapor deposition (OM-CVD) process, an ion implantation process or a thermal diffusion process, which are described in detail hereinafter.

In one embodiment, step 330 includes forming InGaN middle layers 142 and GaN middle layers 144 which are interstacked with each other, and then forming a top layer 146, as shown in FIG. 4. The top layer 146 and the InGaN middle layers 142 may be made of the same material, but two layers are disposed at different positions. For instance, the top layer 146 with a thickness less than 20 Å can be formed by an OM-CVD process. Specifically, the top layer 146 is in-situ doped by a p-type dopant 150a to convert to the p-type InGaN layer 150 by an OM-CVD process. The p-type dopant 150a is a material selected from the group consisting of organic alkaline earth metal, beryllium, magnesium and a combination thereof. The organic alkaline earth metal is a material selected from the group consisting of [bis(cyclopentadienyl) beryllium] (Cp2Be) and [bis(cyclopentadienyl) magnesium] (Cp2Mg) and a combination thereof. For instance, Cp2Mg with 10¹⁹ cm⁻³ can be used in the step of depositing the p-type dopant 150a.

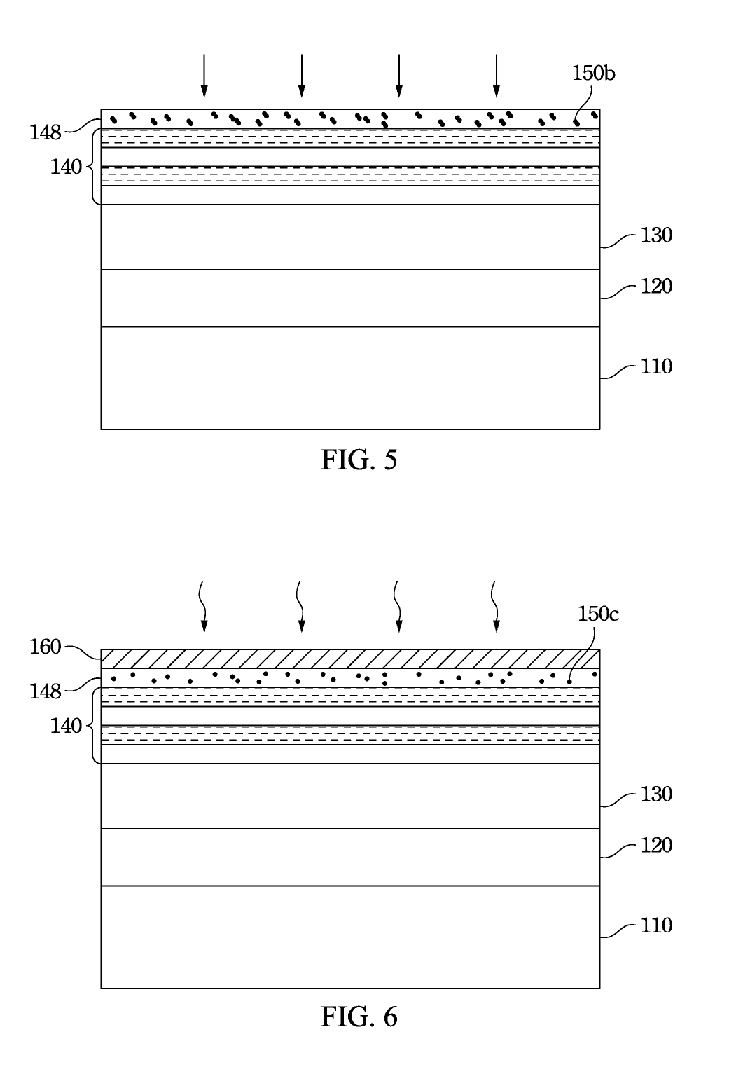

In another embodiment, as shown in FIG. 5, step 340 includes the steps of depositing an U-InGaN layer 148 on the MQW layer 140 by performing an OM-CVD method, and then doping a p-type dopant 150b into the U-InGaN layer 148. The p-type dopant 150b is a material selected from the group consisting of magnesium ions (Mg⁺), beryllium ions (Be⁺) and a combination thereof. For example, the U-InGaN layer 148 with a thickness less than 20 Å is formed by performing an OM-CVD process and then doping Mg⁺ (acted as the p-type dopant 150b) with 10¹⁹ cm⁻³ thereinto.

In further embodiment, as shown in FIG. 6, step 340 includes the steps of depositing an U-InGaN layer 148 on a top surface of the MQW layer 140 by performing an OM-CVD process; forming an alkaline earth metal alloy layer 160 on the U-InGaN layer 148; and diffusing alkaline earth metal ions of the alkaline earth metal alloy layer 160 into the U-InGaN layer 148 by performing an annealing process. In one embodiment, the annealing process is employed in an environment having a temperature higher than or equal to 800° C. The alkaline earth metal alloy layer 160 is a material selected from the group consisting of AuBe alloy, AuMg alloy and a combination thereof. For instance, the U-InGaN layer 148 with a thickness less than 20 Å is formed by carrying out an OM-CVD process, and then depositing an AuBe layer thereon. Next, the annealing process is performed to diffuse beryllium ions into the U-InGaN layer 148.

In step 350, the ITO layer 170 is formed on the p-type InGaN layer 150, as shown in FIG. 1 and FIG. 2. The ITO layer 170 on the p-type InGaN layer 150 can be formed by a sputtering process. The grain size of the ITO layer 170 is in a range of 5 to 1,000 Å. The ITO layer 170 has a surface resistance ranging from 100 to 5 ohms/sq. The ITO layer 170 has a thickness ranging from 5 to 1000 Å. Further, a good ohmic contact between the ITO layer 170 and the p-type InGaN layer 150 is formed.

Sequentially, an etching process is performed to expose a portion of the n-type semiconductor layer 130, as shown in FIG. 1 and FIG. 2.

Finally, a p-type contacting pad 182 and an n-type contacting pad 184 are respectively formed on the ITO layer 170 and the exposed portion of the n-type semiconductor layer 130, as shown in FIG. 1 and FIG. 2, thus to form the LEDs 100, 200. The p-type contacting pad 182 and the n-type contacting pad 184 can be formed by electroplating or depositing processes.

As mentioned above, the LEDs do not include p-type GaN layers. Also, the embodiments of the present disclosure uses an ultra thin p-type InGaN layer combined the high quality ITO layer with small grain size to reduce light absorption and help spread current. Further, the high quality ITO layer can be thinned to reduce light absorption and exhibit enough low surface resistance and good current spreading effect. As such, the LEDs with high light extraction and the method for manufacturing the same can effectively solve those problems above.

Although the present disclosure has been described in considerable detail with reference to certain embodiments thereof, other embodiments are possible. Therefore, the spirit and scope of the appended claims should not be limited to the description of the embodiments contained herein.

It will be apparent to those ordinarily skilled in the art that various modifications and variations may be made to the structure of the present disclosure without departing from the scope or spirit of the disclosure. In view of the foregoing, it is intended that the present disclosure cover modifications and variations thereof provided they fall within the scope of the following claims.

What is claimed is:

1. A light-emitting diode, comprising:
an n-type semiconductor layer disposed on a substrate;
a multi-quantum well (MQW) layer disposed on the n-type semiconductor layer;
a p-type indium gallium nitride layer disposed on the MQW layer; and
an indium tin oxide (ITO) layer disposed on the p-type InGaN layer, wherein the ITO layer has a grain size ranging from 5 to 1,000 angstroms (Å).

2. The light-emitting diode of claim 1, wherein the p-type InGaN layer has a p-type dopant, which is a material selected from the group consisting of beryllium (Be), magnesium (Mg) and a combination thereof.

3. The light-emitting diode of claim 1, wherein the ITO layer is formed by a sputtering process.

4. The light-emitting diode of claim 1, further comprising an alkaline earth metal alloy layer interposed between the p-type InGaN layer and the ITO layer.

5. The light-emitting diode of claim 4, wherein the alkaline earth metal alloy layer is a material selected from the group consisting of gold-beryllium (AuBe) alloy, gold-magnesium (AuMg) alloy and a combination thereof.

6. The light-emitting diode of claim 1, further comprising an undoped gallium nitride (U-GaN) layer interposed between the n-type semiconductor layer and the substrate.

7. The light-emitting diode of claim 1, wherein the p-type InGaN layer has a thickness ranging from 5 to 1,000 Å.

8. The light-emitting diode of claim 7, wherein the p-type InGaN layer has a thickness ranging from 5 to 20 Å.

9. The light-emitting diode of claim 7, wherein the ITO layer has a thickness ranging from 5 to 1,000 Å.

10. The light-emitting diode of claim 7, wherein the ITO layer has surface resistance ranging from 5 to 100 ohms.

11. The light-emitting diode of claim 1, wherein the p-type InGaN layer comprises a material having a general formula of p-InₓGa₁₋ₓN, wherein 0<x<1.

12. The light-emitting diode of claim 1, wherein the n-type semiconductor layer comprises n-type gallium nitride.

13. A method for manufacturing a light-emitting diode, comprising the steps of:
providing a substrate;
forming an n-type semiconductor layer on the substrate;
forming a MQW layer on the n-type semiconductor layer;
forming a p-type InGaN layer on the MQW layer; and
forming an ITO layer on the p-type InGaN layer, wherein the ITO layer has a grain size ranging from 5 to 1,000 Å.

14. The method of claim 13, wherein the MQW layer includes a plurality of InGaN middle layers and a plurality of GaN middle layers interstacked with each other, and a top layer of the MQW layer is an InGaN layer.

15. The method of claim 14, wherein the step of forming the p-type InGaN layer is performed by an organometallic chemical vapor deposition (OM-CVD) process to in-situ dope a p-type dopant into the top layer to convert to the p-type InGaN layer.

16. The method of claim 15, wherein the p-type dopant is a material selected from the group consisting of organic alkaline earth metal, beryllium, magnesium and a combination thereof.

17. The method of claim 16, wherein the organic alkaline earth metal is a material selected from the group consisting of [bis(cyclopentadienyl) beryllium] (Cp2Be) and [bis(cyclopentadienyl) magnesium] (Cp2Mg) and a combination thereof.

18. The method of claim 13, wherein the step of forming the p-type InGaN layer comprises:
depositing an undoped indium gallium nitride (U-InGaN) layer on a top surface of the MQW layer by performing an OM-CVD process; and
doping a p-type dopant into the U-InGaN layer.

19. The method of claim 18, wherein the p-type dopant is a material selected from the group consisting of magnesium ions (Mg⁺), beryllium ions (Be⁺) and a combination thereof.

20. The method of claim 13, wherein the step of forming the p-type InGaN layer comprises:
depositing a U-InGaN layer on a top surface of the MQW layer by performing an OM-CVD process;
forming an alkaline earth metal alloy layer on the U-InGaN layer; and
diffusing the alkaline earth metal ions of the alkaline earth metal alloy layer into the U-InGaN layer by performing an annealing process.

21. The method of claim 20, wherein the annealing process is employed under a temperature higher than or equal to 800° C.

22. The method of claim 20, wherein the alkaline earth metal alloy layer is a material selected from the group consisting of AuBe alloy, AuMg alloy and a combination thereof.

23. The method of claim 13, wherein the ITO layer is formed by a sputtering process.

24. The method of claim 23, wherein the p-type InGaN layer has a thickness ranging from 5 to 1,000 Å.

25. The method of claim 24, wherein the p-type InGaN layer has a thickness ranging from 5 to 20 Å.

26. The method of claim 24, wherein the ITO layer has a thickness ranging from 5 to 1,000 Å.

27. The method of claim 24, wherein the ITO layer has a surface resistance ranging from 5 to 100 ohms.

28. The method of claim of claim 13, wherein the p-type InGaN layer comprises a material having a general formula of p-InₓGa₁₋ₓN, wherein 0<x<1.

29. The method of claim of claim 13, wherein the n-type semiconductor layer comprises n-type gallium nitride.
